(19) United States
(12) Patent Application Publication
(10) Pub. No.: US 2024/0235156 A1
(43) Pub. Date: Jul. 11, 2024

(54) ULTRA-STABLE INTEGRATED LASER ON SILICON

(71) Applicant: Government of the United States of America, as represented by the Secretary of Commerce, Gaithersburg, MD (US)

(72) Inventors: Franklyn John Quinlan, Longmont, CO (US); Scott Alan Diddams, Louisville, CO (US); Kerry John Vahala, Pasadena, CA (US); Joel Wei Guo, Santa Barbara, CA (US); Chao Xiang, Santa Barbara, CA (US); Warren B. Jin, Santa Clara, CA (US); Charles Armand McLemore, Boulder, CO (US); Peter Thomas Rakich, New Haven, CT (US); John Edward Bowers, Santa Barbara, CA (US); Lin Chang, Santa Barbara, CA (US)

(21) Appl. No.: 18/408,456

(22) Filed: Jan. 9, 2024

Related U.S. Application Data
(60) Provisional application No. 63/437,853, filed on Jan. 9, 2023.

(51) Int. Cl. H01S 5/14; H01S 5/02; H01S 5/02253; H01S 5/026

(52) U.S. Cl. CPC H01S 5/142; H01S 5/0215; H01S 5/02253; H01S 5/026

(57) ABSTRACT

An exemplary integrated chip-scale laser assembly includes a chip-scale laser and a compact reference optical cavity optically coupled to an output of the chip-scale laser. The compact reference optical cavity is preferably a vacuum-gap Fabry-Perot (FP) reference cavity. Coupling to the Fabry-Perot cavity from a planar waveguide circuit via bonding may be achieved with metasurfaces and/or grating couplers. The cavity may be edge-coupled to a photonic circuit with a gradient index lens.

### RELATED APPLICATIONS

This application claims the benefit of U.S. Provisional Patent Application Ser. No. 63/437,853 (filed Jan. 9, 2023), which is herein incorporated by reference in its entirety.

### FEDERALLY-SPONSORED RESEARCH AND DEVELOPMENT

This invention was made with United States Government support from the National Institute of Standards and Technology (NIST), an agency of the United States Department of Commerce. The Government has certain rights in this invention.

### COPYRIGHT NOTICE

This patent disclosure may contain material that is subject to copyright protection. The copyright owner has no objection to the facsimile reproduction by anyone of the patent document or the patent disclosure as it appears in the U.S. Patent and Trademark Office patent file or records, but otherwise reserves any and all copyright rights.

### FIELD OF INVENTION

The present invention relates generally to chip-scale lasers, and more particularly to a chip-scale integrated laser with a compact reference optical cavity.

### BACKGROUND

Lasers with hertz linewidths at time scales of seconds are useful for metrology, timekeeping, and manipulation of quantum systems. In particular, for atomic clocks, such lasers are necessary for cooling, trapping, and probing an atomic species. In this arena, the state of the art has demonstrated laser linewidth below 10 mHz and instability as low as 4×10⁻¹⁷. Such frequency stability conventionally relies on bulk-optic lasers and reference cavities, where increased size is leveraged to reduce noise but with the trade-off of cost, hand assembly, and limited applications.

### SUMMARY OF INVENTION

Conventionally, this remarkable performance requires systems of considerable size, complexity, and even cryogenic temperatures, all of which restrict their application to laboratory settings. As the application space evolves, there is increasing interest in, and need for, field deployment of atom-based systems. However, conventional planar waveguide-based lasers enjoy complementary metal-oxide semiconductor scalability yet are fundamentally limited from achieving hertz linewidths by stochastic noise and thermal sensitivity.

Similarly, conventional low-noise microwave oscillators based on cryogenic sapphire resonators take advantage of their higher quality factor (Q) at ultralow temperatures but at the cost of restricting the range of operational environments. An alternative method of generating low-noise microwaves at room temperature is by optical frequency division (OFD). OFD takes advantage of higher Q's of optical resonators and converts stability in the optical domain down to the radio frequency (RF) domain via photodetection of a frequency comb. By stabilizing the comb to a narrow-linewidth laser, the stability of the optical reference is transferred to the photodetected microwave signal, and the phase noise is divided down significantly below what commercially available microwave oscillators can produce. However, the best OFD systems also rely on bulk-optic lasers and cavities, impeding the advancement of field applications requiring extraordinarily low microwave phase noise.

Therefore, described herein is a laser system with a 1-s linewidth of 1.1 Hz and fractional frequency instability below 10-14 to 1 s. This low-noise performance leverages integrated lasers together with an 8-ml vacuum-gap cavity using microfabricated mirrors. All critical components may be lithographically defined on planar substrates, holding potential for high-volume manufacturing. Consequently, this work provides an important advance toward compact lasers with hertz linewidths for portable optical clocks, radio frequency photonic oscillators, and related communication and navigation systems.

According to one aspect of the invention, an integrated chip-scale laser assembly includes a chip-scale laser and a compact reference optical cavity optically coupled to an output of the chip-scale laser.

Optionally, the compact reference optical cavity is a vacuum-gap Fabry-Perot (FP) reference cavity.

Optionally, the chip-scale laser is an integrated self-injection locked laser. Optionally, the chip-scale laser is locked with the Pound-Drever-Hall (PDH) technique to the compact reference optical cavity.

Optionally, coupling to the Fabry-Perot cavity from a planar waveguide circuit via bonding is achieved with at least one of metasurfaces or grating couplers.

Optionally, the cavity is edge-coupled to a photonic circuit with a gradient index lens.

The foregoing and other features of the invention are hereinafter described in greater detail with reference to the accompanying drawings.

### BRIEF DESCRIPTION OF THE DRAWINGS

FIG. 1 shows a schematic illustration of an exemplary laser assembly with a laser coupled to an optical cavity.

FIG. 2 shows a schematic illustration of an exemplary laser assembly with coupling via a grating coupler.

FIG. 3 shows a schematic illustration of an exemplary laser assembly with coupling via a gradient index (GRIN) lens.

FIG. 4 shows a conventional poor-man's isolator.

FIG. 5 shows a chip-integrated poor-man's isolator.

FIG. 6 shows a transfer matrix schematic of the poor-man's system.

FIG. 7 shows a side view of the layered structure of a polarization splitting grating coupler (PSGC), with a single mode optical fiber positioned perpendicularly to the PSGC.

FIG. 8 shows a schematic of co-packaged μFP with a PSGC with a GRIN lens to help with mode matching.

FIG. 9 shows a schematic of co-packaged μFP with a numerically optimized large PSGC to match μFP mode directly.

### DETAILED DESCRIPTION

Integrated lasers and photonic circuits provide a compelling path toward a system-level integration. This vision combines active (lasers, modulators, and detectors), passive (filters and off-chip coupling), and nonlinear elements (frequency combs and frequency converters) while maintaining small overall volume. In addition, heterogeneous silicon photonics offers a path toward realizing ultra-stable, high-precision laser performance in a compact and mobile platform and has demonstrated tremendous scalability with 300-mm wafer-scale fabrication of photonic transceivers at terabits per second for data center applications. Silicon nitride (Si₃N₄) photonics adds even more functionality, taking advantage of complementary metal-oxide semiconductor (CMOS) compatibility, wide bandgap, and low-loss integrated waveguides. Si₃N₄-based lasers have especially leveraged low loss and have demonstrated coherence on par with commercial fiber lasers. However, they are ultimately limited by thermo-refractive noise (TRN), which has kept the fractional frequency instability of planar waveguide and solid dielectric resonators above the 10-13 level typical of quartz oscillators.

Exemplary systems and methods employ a laser using planar microfabricated critical components and exhibiting an integrated linewidth at the 1-Hz level—a value compatible with the performance requirements of compact optical clocks and low-noise RF photonic oscillators. The frequency noise at 1-Hz offset is suppressed by 11 orders of magnitude from that of the free-running diode laser down to the cavity thermal noise limit near 1 Hz²/Hz, decreasing to 10⁻³ Hz²/Hz at 4-kHz offset. The corresponding frequency instability of the laser is below 1×10⁻¹⁴ for averaging times between 1 ms and 1 s, which is significantly below that of the best quartz oscillators. Exemplary systems and methods overcome TRN limits inherent in planar and other solid dielectric reference cavities by joining a microfabricated laser and vacuum-gap Fabry-Perot (FP) reference cavity. Exemplary systems and methods lock an integrated self-injection locked (SIL) laser with the Pound-Drever-Hall (PDH) technique to a vacuum-gap cavity of, e.g., 8 ml, formed from, e.g., lithographically fabricated micromirrors with large, user-defined radius of curvature, pristine surface quality, and high finesse. Surface quality is quantified in term of root-mean-square roughness. Pristine surface quality as used herein means roughness at about the 1 angstrom level or better. High finesse as used herein means preferably over 100,000 and more preferably about several hundred thousands to over 1 million.

Preferably, cavity volume may be about 20 ml or less. More preferably, cavity volume may be about 8 ml or less. Most preferably, cavity volume may be about 0.2 ml or less. Exemplary mirror fabrication techniques allow the sub-20 ml volumes of interest. Conventional techniques are not known to allows the small size indicated while maintaining the high mirror reflectivity desired.

It is important to be able to match the radius of curvature of the mirror to whatever optical mode exits the integrated planar waveguide of the SIL laser. That is, efficient coupling of light between the vacuum-gap FP and the SIL laser depends on fabricating the mirror radius of curvature that best suits the individual SIL implementation.

In contrast to planar waveguide and solid dielectric resonators, the optical mode in a vacuum-gap cavity only interacts with matter at the coated dielectric mirror surfaces; by limiting this interaction to the mirrors, it reduces the influence of stochastic fluctuations and thermal sensitivity inherent to all matter at finite temperatures and achieves an extremely low thermal noise floor. Similarly, compact reference cavities have demonstrated excellent frequency stability but lack a path to scalability and integration. On the other hand, integrated planar waveguide devices have demonstrated a clear path to efficient scalability but suffer from higher frequency noise inherent to the waveguide medium. By using lithographically fabricated micromirrors in exemplary cavities, the noise performance of vacuum-gap systems is utilized while introducing parallel manufacturability previously reserved for planar waveguide systems. The performance of exemplary cavity-stabilized lasers is therefore unprecedented in chip-based devices, yielding a 1.1-Hz linewidth at 1 s, frequency noise following the cavity noise floor down to 10-3 Hz²/Hz at kilohertz offsets, and Allan deviation better than 10-14 averaged out to 1 s. With such scalable components, exemplary systems and methods bridge the gap between silicon photonics and the laser performance required to provide new opportunities for applications in high-precision GPS-free positioning, navigation, and timing; next-generation radar; and commercial 5G communications.

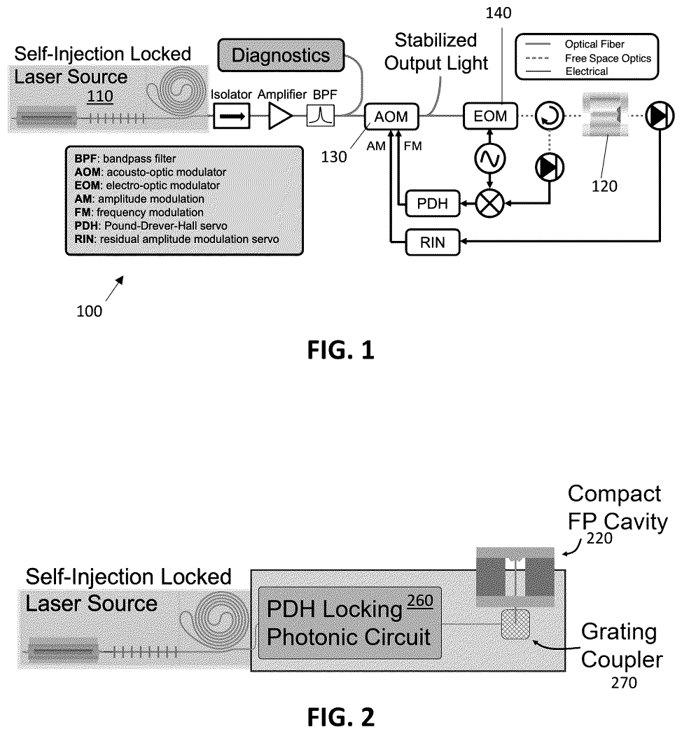

FIG. 1 shows a schematic diagram of components in an exemplary ultra-stable integrated laser assembly 100. The pump source 110 as shown is a fully integrated and electrically-driven heterogeneous III-V/Si/Si₃N₄ laser, fabricated via wafer bonding on a 100-mm wafer. With a 20-mm-long Si3N4 extended distributed Bragg reflector (E-DBR) fully integrated into the laser cavity, the laser exhibits an instantaneous linewidth of 400 Hz with an on-chip output power over 10 mW. Because of the narrowband feedback of the E-DBR, the instantaneous linewidth corresponding to the white frequency noise floor is significantly reduced compared to that of a solitary gain section laser typical of monolithic III-V distributed feedback (DFB) lasers. Although a specific example laser is given herein, the invention is not so limited. Exemplary systems and methods may use any laser, but preferably uses lasers that can be produced in parallel using standard lithographic fabrication technology and techniques.

For further noise suppression, the E-DBR laser may be edge-coupled and self-injection-locked to a high-Q Si₃N₄ spiral resonator on a separate chip (however, other exemplary embodiments may include the resonator on the same chip). High-Q as used above means at or above about 1 million. In this scheme, resonant backward Rayleigh scattering is fed back to the laser, which suppresses the frequency noise at offset frequencies within the resonance linewidth. The noise reduction is proportional to Q² up to the TRN limit, which depends on the modal volume. In one example a measured loaded Q of 126 million and free spectral range (FSR) of 135 MHz was achieved, providing frequency noise superior to that of a commercial fiber laser. In this example, the viability and advantage of using integrated lasers over fiber lasers in terms of size, integration, and noise performance was demonstrated. These example resonators were fabricated on a 200-mm substrate in a CMOS foundry and feature the same cross-sectional waveguide geometry as the Si₃N₄ waveguide in the laser, yielding high modal overlap.

An additional exemplary component to improve noise suppression is a vacuum-gap microfabricated FP (μ-FP) cavity 120 constructed with a lithographically defined micromirror. Microfabrication allows curved mirrors to be etched on a fused silica substrate that may then be optical contact-bonded to a (e.g., 10-mm-long, 25.4-mm-diameter-wide) ultralow expansion (ULE) glass spacer; a fused silica flat mirror may be bonded on the opposite side of the ULE spacer. Both mirrors may be coated with a highly reflective (i.e., approximately >99.999%) dielectric stack. An exemplary resultant cavity features a finesse of approximately 920,000 (Q of 11.8 billion) or better and a linewidth of approximately 16 kHz or better. High finesse is utilized for stabilizing light at the thermal noise floor of the cavity, as finesse directly constrains the maximum achievable discriminator slope used in PDH locking. The overall cavity volume in one exemplary embodiment is approximately 8 ml; while a relatively small cavity volume (preferably 20 ml or less, and more preferably 8 ml or less) is used for integrated systems, it has the additional benefit of reducing the cavity's sensitivity to external vibrations. With careful cavity design and isolation, a low frequency noise floor (e.g., 0.72/f Hz²/Hz (phase noise floor of −4.4/f3 dBc/Hz) or better) and a cavity drift of a few hertz per second or better over multiple hours is achievable.

To stabilize the laser frequency, the E-DBR laser wavelength may first be tuned by current and temperature to match the nearest μ-FP resonance. Once the laser and μ-FP are aligned, the spiral resonator may also be thermally tuned to self-injection lock the E-DBR laser at the same frequency and to passively stabilize the laser. For further PDH locking, the SIL laser is fiber-coupled and stabilized to the μ-FP with an acousto-optic modulator (AOM) 130 as the frequency actuator.

A distinct benefit of using an exemplary integrated SIL laser over a conventional fiber laser (besides the >10× smaller volume) is the lower frequency noise at high offsets. In atomic clock applications, the high offset noise can manifest via aliasing, which becomes increasingly critical at longer atom interrogation times. In the case of PDH locking to an exemplary μ-FP with an exemplary SIL laser versus with a low-noise conventional fiber laser, there is up to a 10-dB difference in frequency noise at offset frequencies between 1 kHz to 1 MHZ, despite the feedback loop roll-off. Even lower high offset frequency noise can be obtained by using the drop port of the spiral resonator, which itself acts as a low-pass filter. Thus, these results demonstrate that an exemplary SIL laser can replace fiber lasers in high-finesse cavity locks, with even better performance at high offset frequencies.

To preserve the hertz-level instantaneous linewidth of the SIL laser, greater feedback loop bandwidth may be used. An electro-optic modulator (EOM) 140 may be used as a frequency actuator with high derivative gain to enable frequency noise suppression out to multi-megahertz offsets. Regardless, by PDH locking the SIL laser, the frequency noise is reduced over six, six, and three orders of magnitude at 1-Hz, 100-Hz, and 10-kHz offsets, respectively. The corresponding phase noise at 100-Hz and 10-KHz offsets is about −65 and −106 dBc/Hz, respectively, with a phase noise floor below −115 dBc/Hz. In a self-referenced OFD scheme, an exemplary laser can support 10-GHz microwave generation with phase noise of −150 dBc/Hz at 100-Hz offset; it is noted, however, that the microwave phase noise floor is likely to be limited by photodetection rather than the laser phase noise floor.

An exemplary laser may be fabricated using sequential wafer bonding and processing of silicon-on-insulator (SOI) and InP onto a 100-mm preprocessed Si₃N₄ wafer, with the lithographic alignment capabilities of a 248-nm-deep ultraviolet stepper. Ninety-nanometer-thick low-pressure chemical vapor deposition Si₃N₄ may be etched and cladded with deuterated SiO₂ to form low-loss Si₃N₄ waveguides and gratings. After planarization of the oxide cladding by chemical-mechanical polishing, a (e.g., 60 mm-by-60 mm SOI) piece may then be bonded, followed by substrate removal and Si processing to form the Si circuits. Cleaved InP-based multi-quantum well gain chiplets (grown on a 2-inch InP substrate, e.g.) may then be bonded, followed by substrate removal, III-V processing, oxide passivation, and metallization. The hybrid III-V/Si gain section may be, for example, 1.5 mm long, and the 20-mm Si3N4 E-DBR may be designed with a normalized grating strength κL_{g} of 1.75, resulting in a measured ˜5-GHz reflection bandwidth and laser oscillation at 1548 nm. The E-DBR feedback strength necessary for laser oscillation is enabled by low-loss intracavity III-V/Si and Si/Si₃N₄ mode converters as well as the low-loss Si₃N₄ grating. This laser may be diced and packaged together with a thermistor and thermoelectric cooler for edge coupling to a resonator chip.

An exemplary spiral resonator may be fabricated on, for example, 200-mm wafers at a CMOS foundry. The round-trip length of the spiral used for subsequent PDH locking may be, for example, 1.41 m, taking up an area of 9.2 mm by 7.2 mm, when limited by a 2-mm design minimum bend radius and 40-μm waveguide pitch for a 100-nm-thick waveguide core. The loaded (intrinsic) Q has been measured, in example embodiments, to be 126 (164) million, yielding an average propagation loss of 0.17 dB/m. These loss values are achieved by annealing at high temperatures over 1000° C. to drive out residual hydrogen. After self-injection locking, the TRN-limited frequency noise is on par with that of commercial fiber lasers, which are typically necessary for PDH locking to ultrahigh-finesse cavities. The spiral resonator may be placed on a thermally controlled stage to shift the resonance frequencies, and the phase may be controlled via piezoelectric control of the gap between chips.

An exemplary micromirror fabrication process may include patterning disks (e.g., three disks) of photoresist onto a superpolished glass substrate, which may then be exposed to a solvent vapor reflow. As the solvent vapor is absorbed into the photoresist, the photoresist disks may be reshaped, producing a small dimple on the top of each. The parabolic shape of this dimple may serve as a template for a concave mirror, which may then be transferred to the substrate through, for example, reactive ion etching. A single fused silica flat mirror may form the opposite mirror. After coating both mirror substrates with a highly reflective (>99.999% at 1550 nm) dielectric stack, they may be optical contact-bonded to opposite sides of a ULE glass spacer (which may be, for example, approximately 10-mm-long and 25.4-mm-diameter-wide). With three concave micromirrors etched on one side, three distinct optical cavities may be formed within a single structure. While the overall cavity volume may be, for example, approximately 8 ml, the cavity volume can be greatly reduced when constructed with only a single micromirror. Furthermore, the capability to fabricate multiple mirrors simultaneously on the same substrate could allow for the parallel manufacture of many single-micromirror cavities by bonding a substrate with an array of micromirrors, a spacer disk with a matching array of holes, and a flat mirror, then dicing the bonded stack.

The length stability of the cavity may be dominated by Brownian fluctuations in the dielectric mirror coatings at short time scales and thermal drift at longer time scales, which may be minimized through cavity design and environmental isolation. Leveraging the versatility of the micromirror fabrication technique, maximizing the micromirror radius of curvature can lead to a large spot size on both end mirrors and effectively average stochastic cavity length fluctuations over a greater area. Fused silica for the mirror substrates contributes to a low noise floor through the material's high mechanical Q, while the ULE spacer may reduce temperature sensitivity of the cavity mode. To further suppress thermal-induced drifts, the μ-FP cavity may be mounted in a custom heat shield inside a vacuum enclosure at 10-7 torr, while temperature feedback is applied to the outside of the vacuum enclosure to improve stability over long time periods. The result of these design and isolation considerations is a fundamental frequency noise floor of roughly 0.72/f Hz²/Hz (phase noise floor of −4.4/f³ dBc/Hz) and long-term cavity drift of a few hertz or better over hour-long time periods.

The optimal strategy for the integration of Fabry-Perot resonators depends heavily on the intended use case. When a Fabry-Perot resonator is used as a stable frequency reference for high-performance laser systems and optical clocks, the frequency of the cavity is typically measured using the PDH locking technique; in this case, laser light reflected from the resonator must be separated from the incident wave and detected with high efficiency to obtain a low noise error signal for feedback stabilization of the laser frequency. Hence, implementation of on-chip PDH locking should use an integration strategy that maps incident and reflected waves to distinct ports of an optical system, permitting direct detection of the reflected wave. Ideally, this same photonic interface would also protect the laser from the frequency-destabilizing effects of back-scattered light by suppressing back reflections from the Fabry-Perot resonator.

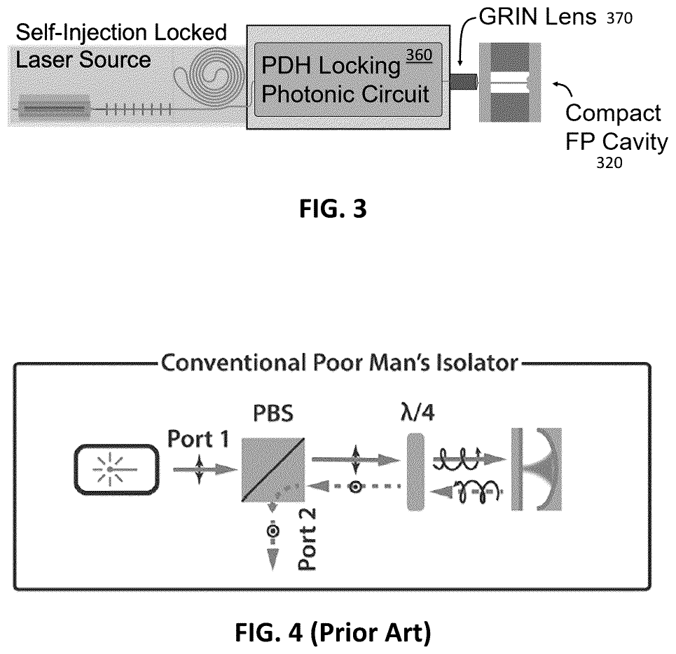

As illustrated in FIG. 2, coupling to a Fabry-Perot cavity 220 from a planar waveguide circuit 260 via bonding may be achieved with metasurfaces and grating couplers 270, similar to those used successfully in atomic systems. As illustrated in FIG. 3, the cavity 320 could be edge-coupled to a photonic circuit 360 with a gradient index (GRIN) lens 370.

An optical circulator is a natural solution to this problem, as it maps incident and reflected waves to distinct optical ports while offering some protection from back reflection. However, the fabrication of isolators and circulators on photonic chips poses a significant challenge due to the incompatibility of the requisite magneto-optic materials with CMOS foundries. To address this challenge, a variety of nonmagnetic isolators and circulators have been demonstrated, which use time modulation to produce non-reciprocal response. However, since these nonmagnetic isolators and circulators are complex and can consume a substantial amount of power, they are not suitable for all applications.

New strategies for passive reflection cancellation could eliminate the need for isolators and circulators in many instances, offering a path to simpler and more power-efficient integrated photonic circuits. One such system that is widely used in free-space optics, colloquially referred to as the poor man's isolator, uses a quarter wave plate and a polarizing beam splitter to separate the incident and reflected optical waves. This system, pictured in FIG. 4, is frequently used instead of an optical circulator to implement PDH locking since it offers lower losses and smaller back reflections. Hence, photonic circuit implementation of such systems could serve as a practical and efficient interface between Fabry-Perot cavities and other free-space systems.

An exemplary reflection cancellation circuit to efficiently interface high-finesse Fabry-Perot resonators with a silicon photonic circuit may be used with and as a part of exemplary laser systems described above. Such exemplary circuits may be modeled after the conventional poor man's isolator and include an interferometer that interfaces to two separate ports of an optimized polarization splitting grating coupler (PSGC) device. Light entering port 1 of the interferometer may be reflected from a fiber-coupled Fabry-Perot resonator before exiting port 2 of the interferometer, yielding spatial separation of the incident and reflected waves as required for on-chip PDH locking. Using inverse design principles to optimize the 2D grating structure, a peak fiber-to-chip coupling efficiency of approximately 55% or better may be achieved, yielding 5.8 dB of loss in a double-pass configuration of the on-chip interface. Interferometric cancellation of reflections produced by this system also yields >9 dB of back-reflection suppression, which could help to protect an on-chip laser source from unwanted back reflections.

Since the degree of back-reflection cancellation is limited only by the imprecision of the splitting ratio of a directional coupler, much higher (>30 dB) back-reflection suppression ratios should be possible with further refinements.

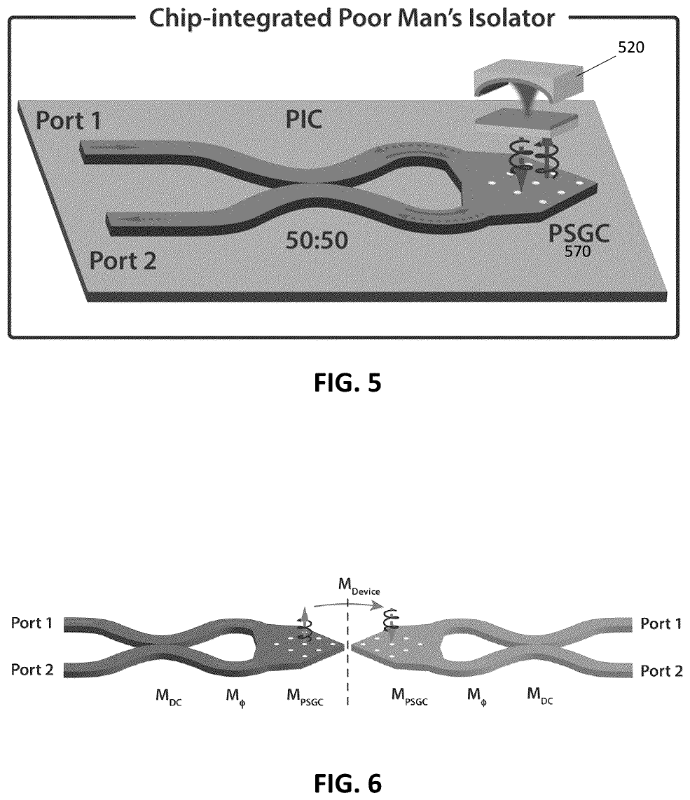

An exemplary reflection cancellation circuit that may be used to interface a high-finesse Fabry-Perot resonator 520 with a silicon photonic circuit is illustrated in FIG. 5. The operating principle of the photonic circuit interface closely mirrors the free-space implementation of the poor man's isolator shown in FIG. 4. In the free-space implementation, p-polarized light entering port 1 passes through the Polarizing Beam Splitter (PBS) and is subsequently converted into right-handed circularly polarized light after it traverses the Quarter Wave Plate (QWP). Upon reflection from the Fabry-Perot resonator, this right-handed circularly polarized wave is converted to a left-handed circularly polarized wave. After traversing the QWP a second time, the left-handed circular polarized wave is converted to an s-polarized wave and is subsequently reflected by the PBS to exit port 2 of the system. Hence, this system protects the laser source from back reflections while yielding spatial separation of the reflected wave as required for on-chip PDH locking. While it has been described herein as being used in an exemplary integrated laser system, an exemplary Fabry-Perot resonator of this type is applicable to any component with a polarization-independent reflection response.

An exemplary circuit implementation of a poor man's isolator system, as shown in FIG. 5, includes a balanced interferometer that incorporates an optimized polarization-splitting grating coupler (PSGC) device 580. In close analogy to the free-space polarizing beamsplitter, the PSGC maps orthogonally polarized waves into separate output waveguide arms. The 1(2) input arm of the PSGC couples to p-polarized (s-polarized) free-space beams that are emitted perpendicular to the grating. Light entering port 1 of this interferometer is split between two waveguides by a 50/50 directional coupler before coupling to the PSGC. Since the directional coupler induces a TT/2 phase difference between the two waveguides (each having identical path lengths), right-handed circularly polarized light is emitted from the PSGC. Upon reflection from the Fabry-Perot resonator (which is assumed to have a polarization independent reflection response), the incident right-handed circular polarization is converted into a left-handed circular polarized wave before entering the PSGC for a second time. This left-handed circular polarized wave is projected into orthogonal linear polarizations by the PSGC 580, meaning that the waves exiting the PSGC 580 now have a −π/2 phase difference. This phase difference causes these two reflected waves to combine within the 50/50 directional coupler, such that all of the reflected light exits port 2 of the interferometer. Hence, this circuit interface yields spatial separation of the incident and reflected waves (as used for on-chip PDH locking) while also producing interferometric cancellation of unwanted back-reflections from port 1.

The transfer matrix formalism may be used to analyze the response of this circuit interface. By mapping the bi-directional two-port system in FIG. 5 onto an equivalent unidirectional two-port system in FIG. 6, 2×2 transfer matrices may be used to analyze the system response. Denoting the incident waves as

$$[ \begin{matrix}{a}_{1} \\ {a}_{2}\end{matrix} ]$$

and the out-going waves as

$$[ \begin{matrix}{b}_{1} \\ {b}_{2}\end{matrix} ] ,$$

one can find the system response by propagating the input waves through transfer matrices associated with each component of the system, as follows:

$$[ \begin{matrix}{b}_{1} \\ {b}_{2}\end{matrix} ] = {M}_{DC} {M}_{ϕ} {M}_{PSGC} {M}_{Device} {M}_{PSGC} {M}_{ϕ} {M}_{DC} [ \begin{matrix}{a}_{1} \\ {a}_{2}\end{matrix} ] . \qquad ( 1 )$$

### Here,

$${M}_{DC} = [ \begin{matrix}r & - iu \\ - iu & r\end{matrix} ] , {M}_{ϕ} = [ \begin{matrix}1 & 0 \\ 0 & {e}^{i ϕ}\end{matrix} ] , {M}_{PSGC} = [ \begin{matrix}α & 0 \\ 0 & α\end{matrix} ] , and$$

$${M}_{Device} = [ \begin{matrix}{\tilde{R}}_{1} & 0 \\ 0 & {\tilde{R}}_{2}\end{matrix} ]$$

are transfer matrices that describe the responses of the directional coupler, differential phase delay, PSGC, and reflective device, respectively.

Here, μ and r=\sqrt{1−μ²} are the splitting coefficients of the directional coupler, ϕ is the phase imbalance between two waveguide segments, a is the coupling coefficient for PSGC, and \tilde{R}₁, \tilde{R}₂ are the complex reflection coefficients for the external device (e.g., Fabry-Perot resonator) for s- and p-polarized light.

Assuming that light is only injected into port 1 (i.e., a₂=0), the above transfer matrix model predicts reflected wave amplitudes b₁=a₁α²(\tilde{R}₁r²−\tilde{R}₂μ²e^{2iϕ}) and b₂=−a₁α²rμ(\tilde{R}₁+\tilde{R}₂e^{2iϕ}). From these expressions, it is possible to null b₁ even in cases where \tilde{R}₁≠\tilde{R}₂. However, the reflection response may be identical for both polarizations. Assuming that \tilde{R}₁=\tilde{R}₁ in the case of 50% power splitting ratio (r=μ=1/\sqrt{2}), it is possible to null b₁ while directing all of the output light be in the case when ϕ=0. Note, however, that the back-reflection suppression ratio,

$${\vert \frac{{b}_{2}}{{b}_{1}} \vert}^{2} = \frac{4 {μ}^{2} ( 1 - {μ}^{2} )}{{\vert 1 - 2 {μ}^{2} \vert}^{2}} ,$$

is sensitive to the splitting coefficient μ. For example, if μ deviates from 1/\sqrt{2} by 14% due to fabrication errors, the back-reflection suppression ratio will decrease to 10 dB from perfect cancellation. Hence, tight control of the power splitting ratio is necessary to obtain a high degree of back-reflection cancellation.

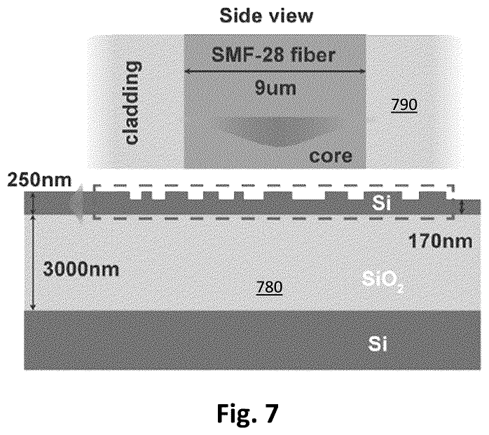

Exemplary circuit interfaces may be created by fabricating a silicon photonic circuit from a Silicon-On-Insulator (SOI) wafer having, for example, a 250 nm thick silicon layer and a three micron silica layer under cladding. E-beam lithography and a reactive-ion etch (etch depth of 80 nm, e.g.) may be used to define both waveguide and grating structures, as shown in FIG. 7. The layered structure of the PSGC 780 is presented, with a single mode optical fiber 790 positioned perpendicularly to the PSGC. To accurately define the desired structure during e-beam exposure, proximity effect correction may be implemented, and through dose tests using hydrogen silsesquioxane (HSQ), an e-beam dose of about 1050 μC/cm², for example, yields excellent performance.

Exemplary circuit interfaces map incident and reflected waves to distinct ports of an optical system, permitting direct detection of the reflected wave for PDH locking to the cavity mode. The PSGC, may be numerically optimized to realize a peak efficiency of about 55% (2.6 dB), enabling an insertion loss as low as about 5.8 dB and a back-reflection suppression ratio of about >9 dB using this system. The demonstrated back reflection suppression ratio may be limited by the imperfection of the splitting ratio of the 50/50 directional coupler. Hence, much higher (>30 dB) back-reflection suppression ratios should be possible with further refinements. For example, the incorporation of a tunable directional coupler and an active phase shifter would not only permit much higher back reflection suppression but would also use such circuit interfaces to efficiently couple to a range of off-chip photonic components.

Looking beyond Fabry-Perot resonators, such reflection cancellation circuits can also serve as versatile interfaces for many other off-chip systems, such as cavity optomechanical systems, vapor cells, sensors, and quantum atomic systems. Such interfaces also possess the potential for integration within a visible light system, which offers notable advantages for atomic and molecular optics applications. This can be achieved by using a different waveguide material, such as silicon nitride, and redesigning the PSGC. Leveraging inverse design algorithms empowers us to impose constraints on the minimal feature, thus facilitating the design of structures that are both efficient and amenable to fabrication. Furthermore, the reduced index contrast of silicon nitride, compared with silicon, also helps alleviate the feature size concern for visible wavelengths.

Furthermore, exemplary systems may be adapted for us in devices exhibiting polarization-dependent reflection response by substituting the 50/50 directional coupler and balanced passive delay with a tunable coupler and tunable phase shifter. Even when the reflection response is not identical for both polarizations, the reflected wave energy can be directed into port 2, thereby ensuring a null back reflection for port 1. This broadens the scope of its application, extending it to a more general case of diffuse scattering, as is often obtained in applications, such as LIDAR. Note that the cancellation process relies on the presence of two modes in free space, which, in the case above, correspond to two different polarizations. If either \tilde{R}₁ or \tilde{R}₂ were to be zero, it would result in vanishing |S₁₂|². While some exemplary reflection cancellation schemes utilize two polarizations of light, this same concept can be implemented in other exemplary systems using only a single polarization, provided that two spatial modes of the same polarization are used to implement reflection cancellation.

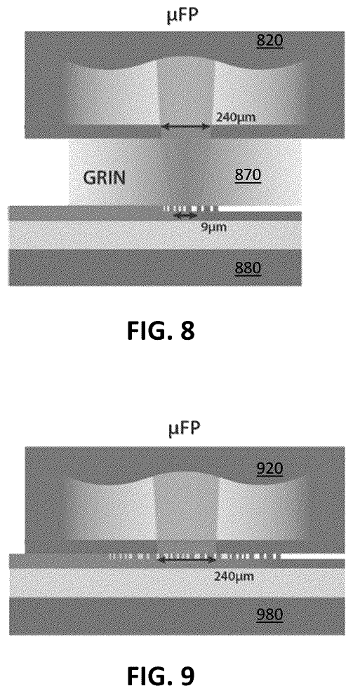

While a fiber umbilical may be utilized to couple off-chip components, a higher degree of integration can be achieved by directly attaching components to the grating coupler. For example, by attaching a GRIN lens 870 to the PSGC 880 as shown in FIG. 8, a compact μFP 820 of the type used here could be integrated into the system to enable compact new optical clock technologies. Moreover, with further computational power, it should be possible to design a PSGC with a larger beam spot size that can directly couple to μFP without the need for a GRIN lens, as shown in FIG. 9, which has like structures labeled with like reference numerals, indexed by 100.

Passive reflection cancellation schemes of the type described herein may eliminate the need for isolators and circulators in many instances, providing simpler and more power-efficient integrated photonic circuits and thus heterogeneous integration between integrated photonic circuits and high-finesse Fabry-Perot resonators that may be utilized for next-generation quantum communications, computation, and time-keeping systems.

The processes described herein may be embodied in, and fully automated via, software code modules executed by a computing system that includes one or more general purpose computers or processors. The code modules may be stored in any type of non-transitory computer-readable medium or other computer storage device. Some or all the methods may alternatively be embodied in specialized computer hardware. In addition, the components referred to herein may be implemented in hardware, software, firmware, or a combination thereof.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

Any logical blocks, modules, and algorithm elements described or used in connection with the embodiments disclosed herein can be implemented as electronic hardware, computer software, or combinations of both. To clearly illustrate this interchangeability of hardware and software, various illustrative components, blocks, modules, and elements have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules described or used in connection with the embodiments disclosed herein can be implemented or performed by a machine, such as a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can include electrical circuitry configured to process computer-executable instructions. In another embodiment, a processor includes an FPGA or other programmable device that performs logic operations without processing computer-executable instructions. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, or algorithm described in connection with the embodiments disclosed herein can be embodied directly in hardware, in a software module stored in one or more memory devices and executed by one or more processors, or in a combination of the two. A software module can reside in RAM memory, flash memory, ROM memory, EPROM memory, EEPROM memory, registers, hard disk, a removable disk, a CD-ROM, or any other form of non-transitory computer-readable storage medium, media, or physical computer storage known in the art. An example storage medium can be coupled to the processor such that the processor can read information from, and write information to, the storage medium. In the alternative, the storage medium can be integral to the processor. The storage medium can be volatile or nonvolatile.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix (s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

What is claimed is:

1. An integrated chip-scale laser assembly comprising:
a chip-scale laser; and
a compact reference optical cavity optically coupled to an output of the chip-scale laser.

2. The integrated chip-scale laser assembly of claim 1, wherein the compact reference optical cavity is a vacuum-gap Fabry-Perot (FP) reference cavity.

3. The integrated chip-scale laser assembly of claim 1, wherein the chip-scale laser is an integrated self-injection locked laser.

4. The integrated chip-scale laser assembly of claim 1, wherein the chip-scale laser is locked with the Pound-Drever-Hall (PDH) technique to the compact reference optical cavity.

5. The integrated chip-scale laser assembly of claim 2, wherein coupling to the Fabry-Perot cavity from a planar waveguide circuit via bonding is achieved with at least one of metasurfaces or grating couplers.

6. The integrated chip-scale laser assembly of claim 1, wherein the cavity is edge-coupled to a photonic circuit with a gradient index lens.
